(19) United States
(12) Patent Application Publication
(10) Pub. No.: US 2008/0029810 A1
(43) Pub. Date: Feb. 7, 2008

(54) METHODS OF FABRICATING SEMICONDUCTOR DEVICES HAVING BURIED GATES AND RELATED SEMICONDUCTOR DEVICES

(75) Inventors: Bong Soo Kim, Gyeonggi-do (KR); Yun-Gi Kim, Gyeonggi-do (KR); Hyeoung-Won Seo, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/563,365

(22) Filed: Nov. 27, 2006

(30) Foreign Application Priority Data
Aug. 4, 2006 (KR) 2006-0073666

(51) Int. Cl. H01L 29/78; H01L 21/336

(52) U.S. Cl. 257/330; 438/589; 438/270; 438/296; 257/334

(57) ABSTRACT

Methods of fabricating semiconductor devices capable of maintaining a liner on both sidewalls of an active region overlapping a gate are provided. An isolation trench defining an active region is formed in a semiconductor substrate. A liner is formed on sidewalls of the active region. An isolation layer filling the isolation trench is formed. A hard mask pattern is formed on the semiconductor substrate having the liner and the isolation layer. A gate trench crossing the active region is formed using the hard mask pattern as an etching mask. A gate is formed in the gate trench. After forming the gate, the hard mask pattern is removed. A gate capping pattern is formed on the gate.

### CROSS-REFERENCE TO RELATED APPLICATION

This application claims the benefit under 35 U.S.C. § 119 of Korean Patent Application No. 2006-0073666, filed Aug. 4, 2006, the contents of which are hereby incorporated herein by reference in their entirety.

### FIELD OF THE INVENTION

The present invention relates to methods of fabricating semiconductor devices, and more particularly, to semiconductor devices having buried gates and methods of fabricating the same.

### BACKGROUND OF THE INVENTION

MOSFET transistors having recessed channels are known in the art. These transistors are often used in highly integrated semiconductor devices, as the recess channel MOSFETS may be very small and may reduce or eliminate the short channel effect. However, in a recess channel MOSFET, the gate electrode projects over the semiconductor substrate. This projecting gate electrode may increase the difficulty of subsequent planarization and/or contact plug forming processing steps. In addition, upper corners of the recessed channel region may cause leakage current due to an electric field crowding effect. Further, forming the projected gate electrode may require a very precise patterning process.

In order to address the above-mentioned problems with recessed channel MOSFETS, semiconductor devices having buried gates have been proposed. FIG. 1 is a plan view of a conventional semiconductor device having a buried gate. FIGS. 2 to 4 are cross-sectional diagrams illustrating a method of fabricating a conventional semiconductor device having a buried gate. In FIGS. 2 to 4, regions 1 are cross-sectional diagrams taken along line I-I′ of FIG. 1, regions 2 are cross-sectional diagrams taken along line II-II′ of FIG. 1, and regions 3 are cross-sectional diagrams taken along line III-III′ of FIG. 1.

As shown in FIGS. 1 and 2, a liner 14 and an isolation layer 15 that define an active region 13 are sequentially formed in a predetermined region of a semiconductor substrate 11. The liner 14 covers sidewalls of the active region 13. The liner 14 may comprise, for example, a silicon nitride layer, and the isolation layer 15 may comprise, for example, a silicon oxide layer.

A hard mask pattern 17 is formed on the semiconductor substrate 11 having the liner 14 and the isolation layer 15. The hard mask pattern 17 may comprise, for example, a silicon nitride layer. The active region 13 and the isolation layer 15 are then etched using the hard mask pattern 17 as an etching mask to form a gate trench 19. An upper surface of the liner 14 between the active region 13 and the isolation layer 15 in the gate trench 19 is exposed by this etch process, as shown in region 2 of FIG. 2.

As shown in FIGS. 1 and 3, the hard mask pattern 17 may then be removed using, for example, an isotropic etching process having a high etch rate with respect to the silicon nitride hard mask pattern 17. When the hard mask pattern 17 is removed, the exposed portion of the liner 14 in the gate trench 19 may also be etched. As a result, a gap 21 may be formed between the active region 13 and the isolation layer 15 in the gate trench 19, as shown in region 2 of FIG. 3.

As shown in FIGS. 1 and 4, a gate dielectric layer 23 may then be formed on the active region 13, and a buried gate electrode 25 may be formed on the dielectric layer 23 in the gate trench 19. Then, a gate capping pattern 27 is formed to cover the buried gate electrode 25 and fill the gate trench 19. During the formation of the buried gate electrode 25, a gate extension 25E may be formed in the gaps 21, as shown in region 2 of FIG. 4. The gate dielectric layer 23 is also formed between the gate extension part 25E and the active region 13.

A semiconductor device having a buried word line is disclosed in U.S. Pat. No. 6,770,535, entitled “Semiconductor Integrated Circuit Device and Process for Manufacturing the Same.”

### SUMMARY

Pursuant to embodiments of the present invention, methods of fabricating a semiconductor device capable of maintaining a liner on both sidewalls of an active region overlapping a gate are provided. Pursuant to these methods, an isolation trench is formed in a semiconductor substrate to define an active region having sidewalls. A liner is then formed on the sidewalls of the active region, and an isolation layer is formed in the isolation trench. A hard mask pattern is formed on the semiconductor substrate having the liner and the isolation layer, and a gate trench is then formed that crosses over the active region using the hard mask pattern as an etching mask. A gate is formed in the gate trench that covers an exposed top surface of the liner. Finally, the hard mask pattern is removed after the gate is formed.

In some embodiments, the gate trench may be formed by etching portions of the active region, the liner and the isolation layer. In some embodiments, this etching process may be performed such that top surfaces of the etched portions of the active region, the liner and the isolation layer are etched to the same height above a bottom surface of the semiconductor substrate. In other embodiments, the etching process may be performed such that top surfaces of the etched portions of the liner and the isolation layer have a lower level than a top surface of the etched portion of the active region. In still other embodiments, the etching process may be performed such that the top surfaces of the etched portions of the liner and the isolation layer have the same level above a bottom surface of the semiconductor substrate.

The liner may comprise a nitride layer. The liner may comprise an inner liner that covers the sidewalls of the active region and an outer liner that covers the inner liner. The hard mask pattern and the liner may be formed of the same material such as, for example, a nitride layer. The gate may be formed by forming a gate dielectric layer in the semiconductor substrate having the gate trench, and then forming a gate electrode in the gate trench on the gate dielectric layer. The gate electrode may comprise, for example, a titanum nitride (TiN) layer. The top surface of the gate electrode may be is lower than a top surface of the active region.

In some embodiments, the method may also include forming a source region in the active region adjacent to a first side of the gate and forming a drain region in the active region adjacent to a second side of the gate. These methods may further include forming a dummy dielectric layer on the active region and forming a dummy gate conductive layer on the dummy dielectric layer before forming the hard mask pattern.

Pursuant to further embodiments of the present invention, semiconductor devices are provided which include an isolation layer that defines an active region in a semiconductor substrate. A liner is provided between the active region and the isolation layer. A gate is disposed in a gate trench, the gate extending across the active region onto the liner and the isolation layer. A gate capping pattern is on the gate. In these devices, a top surface of the liner under the gate is disposed at the same level as a top surface of the isolation layer under the gate. In these devices, the gate trench may extend onto the isolation layer. A top surface of the isolation layer under the gate may be disposed at a level lower than or equal to a top surface of the active region under the gate. The liner may comprise a nitride layer, and may include an inner liner covering sidewalls of the active region and an outer liner covering the inner liner. The gate may comprise a gate electrode-having a top surface that is lower than a top surface of the active region and a gate dielectric layer between the active region and the gate electrode. The gate capping pattern may have a bottom surface that is lower than a top surface of the active region.

### BRIEF DESCRIPTION OF THE DRAWINGS

The accompanying drawings, which are included to provide a further understanding of the invention and are incorporated in and constitute a part of this application, illustrate certain embodiment(s) of the invention.

FIG. 1 is a plan view of a conventional semiconductor device having a buried gate.

FIGS. 2 to 4 are cross-sectional diagrams illustrating a method of fabricating a conventional semiconductor device having a buried gate.

FIG. 5 is flowchart illustrating methods of fabricating semiconductor devices in accordance with embodiments of the present invention.

FIG. 6 is a plan view of semiconductor devices in accordance with embodiments of the present invention.

FIGS. 7A, 8A, 9A, 10A, 11A, 12A and 13A are cross-sectional diagrams taken along line V-V′ of FIG. 6, illustrating methods of fabricating semiconductor devices having buried gates in accordance with first embodiments of the present invention.

FIGS. 7B, 8B, 9B, 10B, 11B, 12B, and 13B are cross-sectional diagrams taken along line VII-VII′ of FIG. 6, illustrating methods of fabricating semiconductor devices having buried gates in accordance with the first embodiments of the present invention.

FIG. 14A is a cross-sectional diagram taken along line V-V′ of FIG. 6, illustrating methods of fabricating semiconductor devices having buried gates in accordance with second embodiments of the present invention.

FIG. 14B is a cross-sectional diagram taken along line VII-VII′ of FIG. 6, illustrating methods of fabricating semiconductor devices having buried gates in accordance with the second embodiments of the present invention.

FIG. 15A is a cross-sectional diagram taken along line V-V′ of FIG. 6, illustrating methods of fabricating semiconductor devices having buried gates in accordance with third embodiments of the present invention.

FIG. 15B is a cross-sectional diagram taken along line VII-VII′ of FIG. 6, illustrating methods of fabricating semiconductor devices having buried gates in accordance with the third embodiments of the present invention.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Other words used to describe the relationship between elements should be interpreted in a like fashion (i.e., “between” versus “directly between”, “adjacent” versus “directly adjacent”, etc.).

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this disclosure and the relevant art and will not be interpreted in an idealized or overly formal sense unless expressly so defined herein.

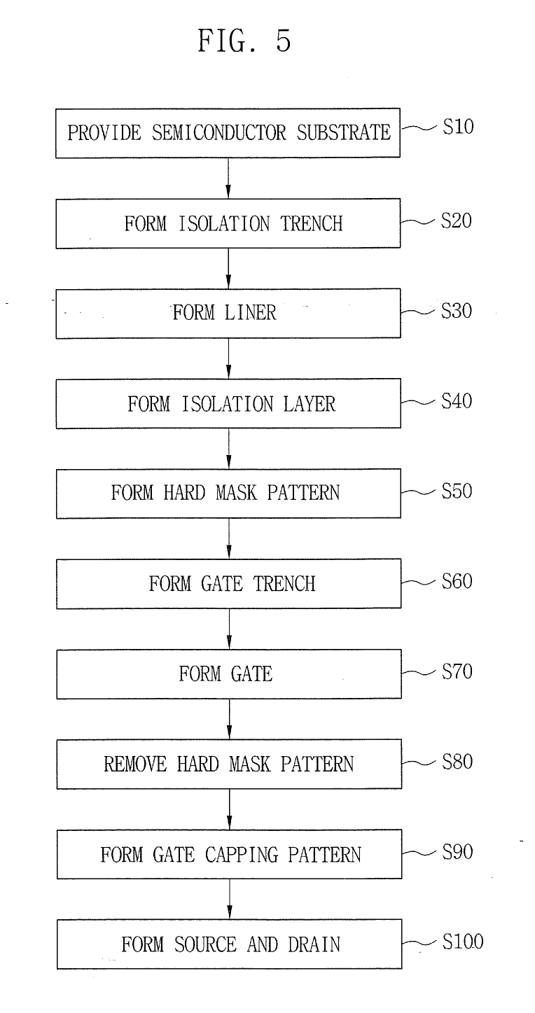

FIG. 5 is flowchart illustrating methods of fabricating semiconductor devices in accordance with embodiments of the present invention. As shown in FIG. 5, these methods may include providing a semiconductor substrate (S10), forming an isolation trench (S20), forming a liner (S30), forming an isolation layer (S40), forming a hard mask pattern (S50), forming a gate trench (S60), forming a gate (S70), removing the hard mask pattern (S80), forming a gate capping pattern (S90), and forming a source and a drain (S100).

When the hard mask pattern is removed (S80 in FIG. 5), the gate prevents the liner formed on sidewalls of the active region overlapping the gate from being in contact with an etching gas or an etching solution. Therefore, even when the liner is formed of the same material as the hard mask pattern, the liner may be maintained on the sidewalls of the active region overlapping the gate.

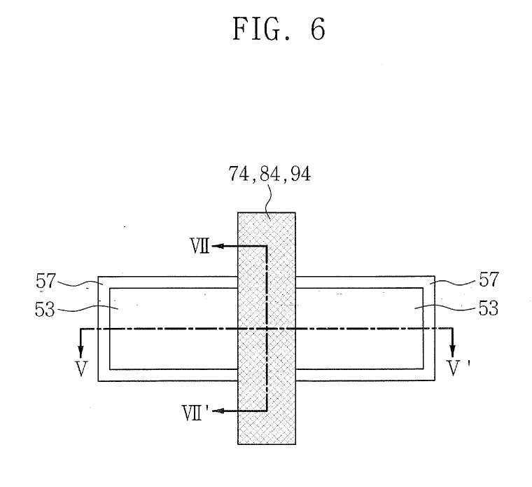

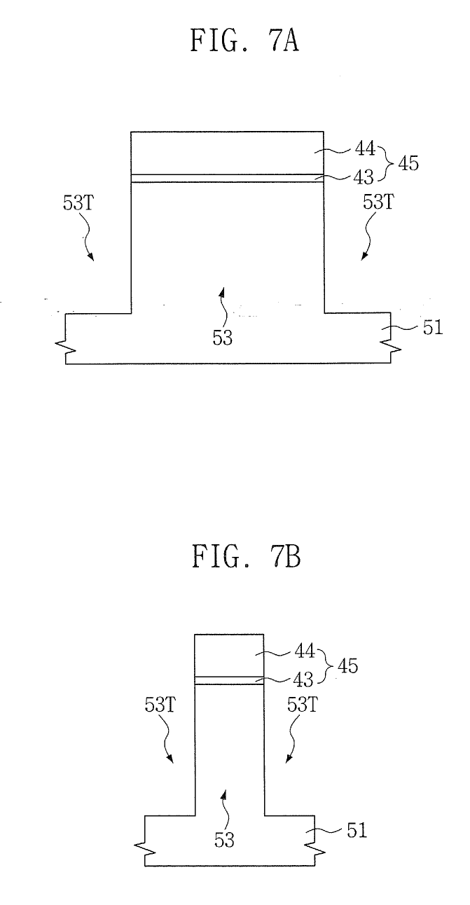

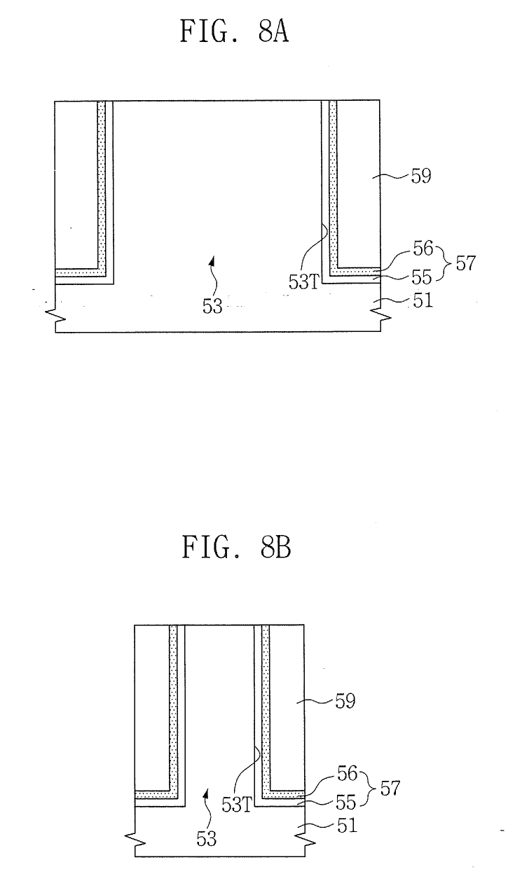

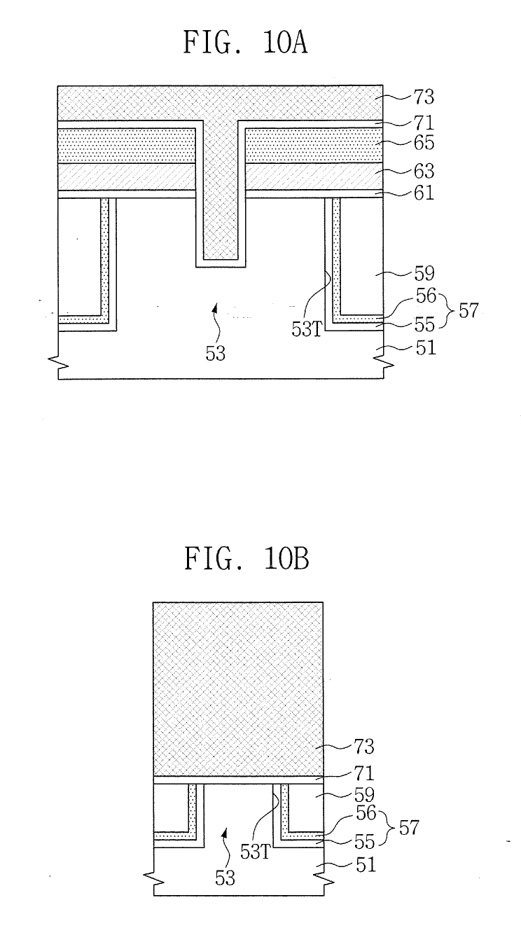

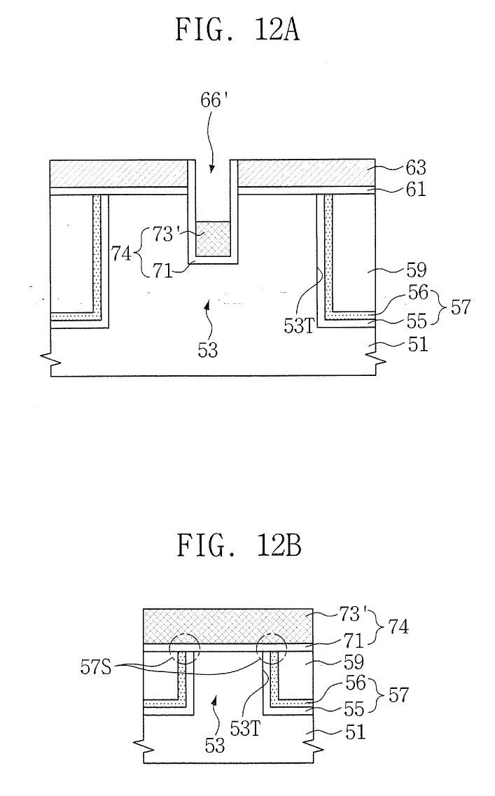

FIG. 6 is a plan view of semiconductor devices in accordance with embodiments of the present invention. FIGS. 7A, 8A, 9A, 10A, 11A, 12A and 13A are cross-sectional diagrams taken along line V-V′ of FIG. 6, illustrating methods of fabricating semiconductor devices having buried gates in accordance with first embodiments of the present invention. FIGS. 7B, 8B, 9B, 10B, 11B, 12B and 13B are cross-sectional diagrams taken along line VII-VII′ of FIG. 6, illustrating methods of fabricating semiconductor devices having buried gates in accordance with first embodiments of the present invention.

Referring to FIGS. 5, 6, 7A and 7B, the methods of fabricating semiconductor devices in accordance with the first embodiments of the present invention include providing a semiconductor substrate 51 (S10 of FIG. 5). The semiconductor substrate 51 may, for example, be a silicon wafer. As shown in FIGS. 7A and 7B, an isolation trench 53T may be formed to define an active region 53 in the semiconductor substrate 51 (S20 of FIG. 5). Specifically, a trench mask pattern 45 may be formed on the semiconductor substrate 51. The trench mask pattern 45 may be formed by sequentially depositing a buffer pattern 43 and a mask pattern 44. The buffer pattern 43 may comprise, for example, a silicon oxide layer such as a thermal oxide layer. The mask pattern 44 may comprise, for example, a nitride layer such as a silicon nitride layer. Alternatively, the trench mask pattern 45 may comprise a photoresist pattern. The semiconductor substrate 51 may be anisotropically etched using the trench mask pattern 45 as an etching mask to form the isolation trench 53T.

As shown in FIGS. 5, 6, 8A and 8B, a liner 57 may be formed on an inner wall of the isolation trench 53T (S30 of FIG. 5). The liner 57 may include an inner liner 55 that covers sidewalls of the active region 53, and an outer liner 56 that covers the inner liner 55. The inner liner 55 may comprise, for example, a silicon oxide layer such as a thermal oxide layer. The outer liner 56 may comprise, for example, a nitride layer such as a silicon nitride layer. The liner 57 may be formed to a uniform thickness on the semiconductor substrate 51. In some embodiments, the liner 57 may comprise only the outer liner 56.

Next, an isolation layer 59 may be formed in the semiconductor substrate 51 having the liner 57 (S40 of FIG. 5). The isolation layer 59 may fill the isolation trench 53T. The isolation layer 59 may comprise, for example, a silicon oxide layer such as a high density plasma oxide layer. Either before, during or after the formation of the isolation layer 59 (or some combination thereof) the trench mask pattern 45 may be removed. As a result, a top surface of the active region 53 may be exposed. The liner 57 may cover sidewalls of the active region 53. The isolation trench 53T may be filled with the isolation layer 59.

Referring to FIGS. 5, 6, 9A and 9B, a dummy dielectric layer 61 may be formed on the active region 53. A dummy gate conductive layer 63 may be formed on the dummy dielectric layer 61. The dummy dielectric layer 61 may comprise, for example, a silicon oxide layer or a high-k dielectric layer. The dummy gate conductive layer 63 may comprise, for example, a polysilicon layer, a metal silicide layer, a metal layer, or a combination thereof. The dummy dielectric layer 61 may function as a gate dielectric layer of a peripheral circuit region (not shown). The dummy gate conductive layer 63 may function as a gate electrode of the peripheral circuit region (not shown). It will also be appreciated that the dummy dielectric layer 61 and/or the dummy gate conductive layer 63 may be omitted.

A hard mask pattern 65 may be formed on the dummy gate conductive layer 63 (S50 of FIG. 5). The hard mask pattern 65 may comprise a material that has etch selectivity with respect to the active region 53 and the isolation layer 59. In some embodiments, the hard mask pattern 65 may comprise the same material as the liner 57. That is, the hard mask pattern 65 may include a nitride layer such as a silicon nitride layer. The hard mask pattern 65 may have an opening that partially exposes a top surface of the semiconductor substrate 51.

A gate trench 66 may be formed in the semiconductor substrate 51 using the hard mask pattern 65 as an etching mask (S60 of FIG. 5). This gate trench 66 may be formed by sequentially etching the dummy gate conductive layer 63, the dummy dielectric layer 61 and the active region 53.

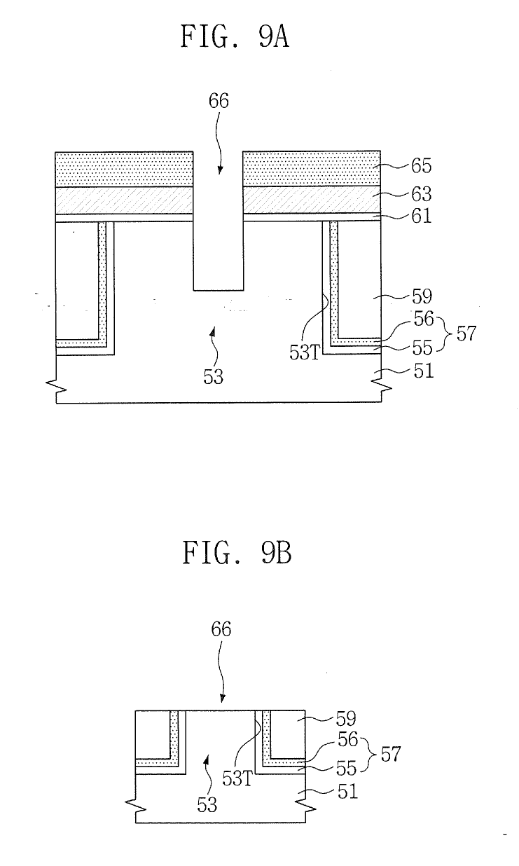

In some embodiments of the present invention, the etching process for forming the gate trench 66 may comprise an anisotropic etching process having a uniform etch rate with respect to the active region 53, the liner 57 and the isolation layer 59. In such embodiments, top surfaces of the active region 53, the liner 57, and the isolation layer 59 may be exposed at the same level on a bottom surface of the gate trench 66, as shown in FIG. 9B.

The gate trench 66 may cross the active region 53 and the liner 57 and the isolation layer 59 at both sides of the active region 53. Top surfaces of the active region 53, the liner 57 and the isolation layer 59 may be exposed at the bottom surface of the gate trench 66. As shown in FIG. 9B, the top surfaces of the active region 53, the liner 57 and the isolation layer 59 may be formed to have the same height or level above a bottom surface of the semiconductor substrate 51.

In other embodiments, the etching process for forming the gate trench 66 may comprise an anisotropic etching process having different etch rates with respect to the active region 53, the liner 57 and the isolation layer 59. In these embodiments, the top surface of the isolation layer 59 may be exposed at the bottom surface of the gate trench 66 at a level higher or lower than the active region 53. The top surfaces of the liner 57 and the isolation layer 59 may have the same level.

In still other embodiments, the etching process for forming the gate trench 66 may comprise an anisotropic etching process having a higher etch rate with respect to the active region 53 than the liner 57 and the isolation layer 59. In these embodiments, the gate trench 66 may be formed in the active region 53. The liner 57 may be maintained on sidewalls of the gate trench 66.

Referring to FIGS. 5, 6, 10A and 10B, a gate dielectric layer 71 may be formed on the semiconductor substrate 51 having the gate trench 66. The gate dielectric layer 71 may cover the inner walls of the gate trench 66 and the hard mask pattern 65. The gate dielectric layer may comprise, for example, a silicon oxide layer or a high-k dielectric layer.

A gate conductive layer 73 may be formed on the gate dielectric layer 71. The gate conductive layer 73 may comprise, for example, a polysilicon layer, a metal silicide layer, a metal layer, a titanium nitride (TiN) layer or a combination thereof. The gate conductive layer 73 may fill the gate trench 66 and cover the hard mask pattern 65.

Referring to FIGS. 5, 6, 11A and 11B, a gate electrode 73′ may be formed by partially removing the gate conductive layer 73. The gate dielectric layer 71 and the gate electrode 73′ may constitute a gate 74 (S70 of FIG. 5).

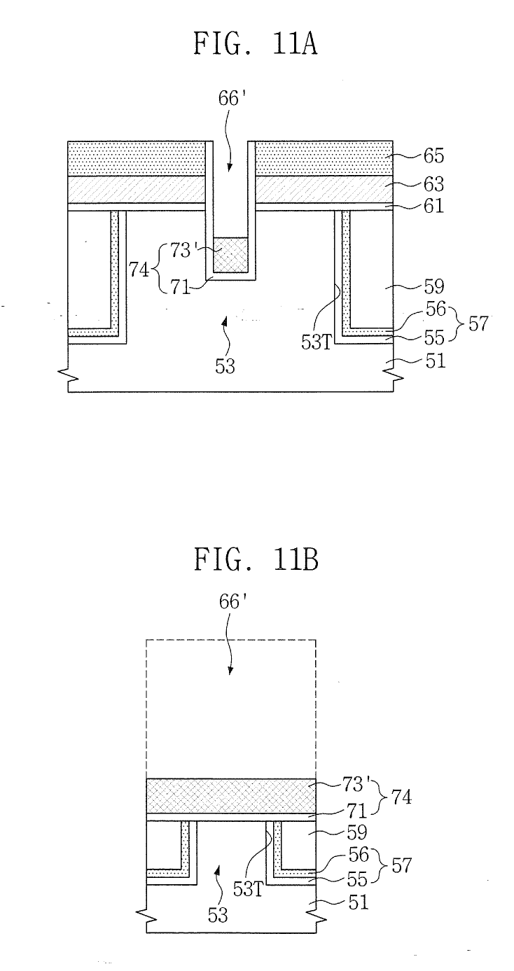

The process of forming the gate electrode 73′ may include etching-back the gate conductive layer 73. The gate electrode 73′ may partially fill the gate trench 66, leaving an upper gate trench 66′ above the gate electrode 73′. As shown in FIG. 11A, a top surface of the gate electrode 73′ may be below the top surface of the active region 53. During the formation of the gate electrode 73′, the hard mask pattern 65 may be exposed.

Next, as shown in FIGS. 5, 6, 12A and 12B, the hard mask pattern 65 may be removed (S80 of FIG. 5) using, for example, an isotropic etching process. For instance, when the hard mask pattern 65 is a silicon nitride layer, the hard mask pattern 65 may be removed using dry etching or wet etching conditions having a high etch rate with respect to silicon nitride.

During the removal of the hard mask pattern 65, the gate 74 may function as an etching mask that prevents introduction of an etching gas or an etching solution into a “liner remaining area” 57S that is covered by the overlapping gate 74. Therefore, even though the liner 57 may be formed of the same material as the hard mask pattern 65, the liner 57 may be maintained on both sidewalls of the active region 53 under the gate 74.

As shown in FIGS. 5, 6, 13A and 13B, a gate capping pattern 75 may be formed on the gate 74 (S90 of FIG. 5). The gate capping pattern 75 may comprise, for example, an insulating layer such as a silicon oxide layer. The gate capping pattern 75 may cover the gate 74.

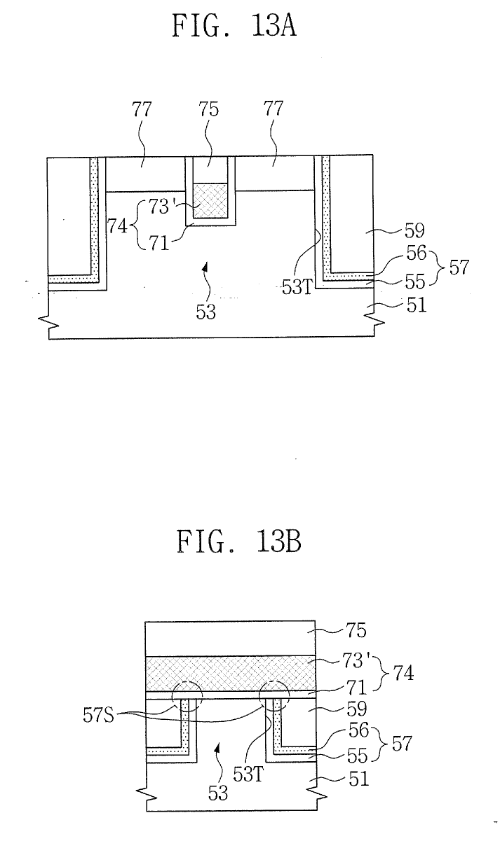

The dummy gate conductive layer 63 and the dummy dielectric layer 61 may be removed to expose the active region 53. The gate capping pattern 75 may fill the upper gate trench 66′. As shown in FIG. 13A, top surfaces of the gate capping pattern 75 and the active region 53 may be at the same level above the bottom surface of the semiconductor substrate. The gate 74 may be buried at a level lower than the top surface of the active region 53. The top surface of the active region 53 at both sides of the gate 74 may be exposed. It will also be appreciated that the dummy gate conductive layer 63 and the dummy dielectric layer 61 may alternatively be removed before forming the gate capping pattern 75.

Source and drain regions 77 may be formed in the active region 53 at both sides of the gate 74 (S100). The source and drain regions 77 may be high-concentration impurity regions. The active region 53, the gate 74, and the source and drain regions 77 may constitute a transistor.

As described above, according to the first embodiments of the present invention, the hard mask pattern 65 is removed after the gate 74 is formed. Therefore, it is possible to reduce and/or prevent introduction of an etching gas or an etching solution into the “liner remaining area” 57S shown in FIG. 13B. Therefore, although the liner 57 may comprise the same material as the hard mask pattern 65, it is possible to maintain the liner 57 on both sidewalls of the active region 53 under the gate 74.

A semiconductor device in accordance with the first embodiments of the present invention will now be described with reference to FIGS. 6, 13A and 13B. As shown in FIGS. 6, 13A and 13B, the semiconductor device in accordance with the first embodiments of the present invention includes an isolation layer 59 provided in the semiconductor substrate 51. The isolation layer 59 may fill an isolation trench 53T that defines an active region 53 in the semiconductor substrate 51. The isolation layer 59 may be a silicon oxide layer. A liner 57 may be provided between the isolation layer 59 and the active region 53 that covers the inner walls of the isolation trench 53T.

The liner 57 may include an inner liner 55 covering sidewalls of the active region 53, and an outer liner 56 covering the inner liner 55. The inner liner 55 may be a silicon oxide layer such as a thermal oxide layer. The outer liner 56 may be a nitride layer such as a silicon nitride layer. The liner 57 may be formed to a uniform thickness on the semiconductor substrate 51. In some embodiments, the inner liner 55 may be omitted.

A gate 74 that crosses the active region 53 may be provided. The gate 74 may partially fill a gate trench 66 (see FIG. 9A). The gate 74 may include a gate dielectric layer 71 that covers inner walls of the gate trench 66, and a gate electrode 73′ that is disposed on the gate dielectric layer 71. The top surface of the gate electrode 73′ may lower than a top surface of the active region 53 adjacent to the gate 74.

The gate dielectric layer 71 may comprise, for example, a silicon oxide layer or a high-k dielectric layer. The gate electrode 73′ may be a polysilicon layer, a metal silicide layer, a metal layer, a titanium nitride (TiN) layer or a combination thereof.

A gate capping pattern 75 may be provided on the gate electrode 73′. The gate capping pattern 75 may be an insulating layer such as a silicon oxide layer. The gate capping pattern 75 may cover the gate 74. Top surfaces of the gate capping pattern 75 and the active region 53 may be disposed at substantially the same level.

Source and drain regions 77 may be disposed in the active region 53 at both sides of the gate 74. The source and drain regions 77 may be high-concentration impurity regions. The active region 53, the gate 74 and the source and drain regions 77 may constitute a transistor.

The gate trench 66 may cross the active region 53 and the isolation layer 59. As such, the gate 74 may extend onto the isolation layer 59. Surfaces of the active region 53, the liner 57 and the isolation layer 59 that are under the gate 74 may be disposed at the same level.

A “liner remaining area” 57S may be provided on both sidewalls of the active region 53 under the gate 74. That is, the liner 57 on both sidewalls of the active region 53 under the gate 74 may have surfaces disposed at the same lever as the portion of the isolation layer 59 that is under the gate 74.

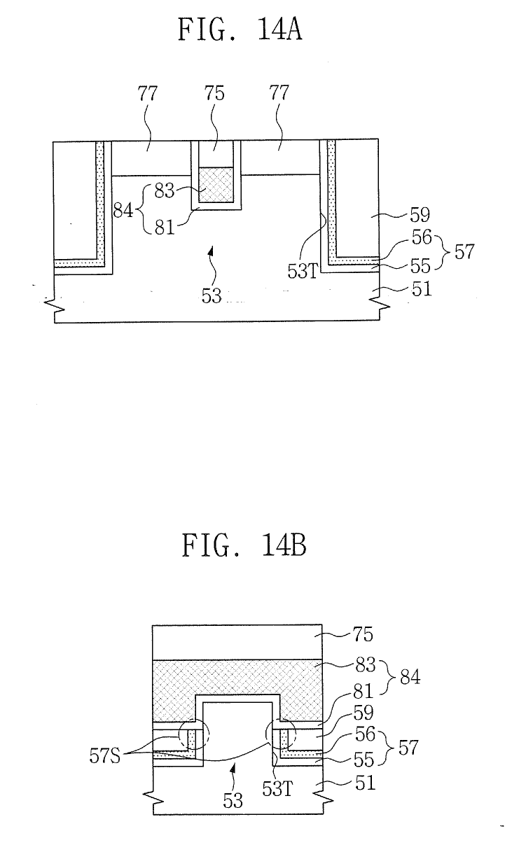

FIG. 14A is a cross-sectional diagram taken along line V-V′ of FIG. 6, illustrating methods of fabricating semiconductor devices having buried gates in accordance with second embodiments of the present invention, and FIG. 14B is a cross-sectional diagram taken along line VII-VII′ of FIG. 6. As shown in FIGS. 6, 14A and 14B, semiconductor devices in accordance with the second embodiments of the present invention include an isolation layer 59 provided in a semiconductor substrate 51. The isolation layer 59 may fill an isolation trench 53T that defines an active region 53 in the semiconductor substrate 51. The isolation layer 59 may comprises for example, a silicon oxide layer. A liner 57 may be provided between the isolation layer 59 and the active region 53 so as to cover the inner walls of the isolation trench 53T.

The liner 57 may include an inner liner 55 that covers sidewalls of the active region 53, and an outer liner 56 that covers the inner liner 55. The inner liner 55 may comprise, for example, a silicon oxide layer such as a thermal oxide layer. The outer liner 56 may comprise, for example, a nitride layer such as a silicon nitride layer. The liner 57 may be formed to a uniform thickness on the semiconductor substrate 51. In some embodiments, the inner liner 55 may be omitted.

A gate 84 may be provided that crosses the active region 53. The gate 84 may partially fill a gate trench 66 (see FIG. 9A). The gate 84 may include a gate dielectric layer 81 that covers inner walls of the gate trench 66, and a gate electrode 83 that is disposed on the gate dielectric layer 81. A top surface of the gate electrode 83 may be lower than a top surface of the active region 53 adjacent to the gate 84.

The gate dielectric layer 81 may comprise, for example, a silicon oxide layer or a high-k dielectric layer. The gate electrode 83 may comprise, for example, a polysilicon layer, a metal silicide layer, a metal layer, or a combination thereof. The gate electrode 83 may be a titanium nitride (TiN) layer.

A gate capping pattern 75 may be provided on the gate electrode 83. The gate capping pattern 75 may comprise an insulating layer such as a silicon oxide layer. The gate capping pattern 75 may cover the gate 84. Top surfaces of the gate capping pattern 75 and the active region 53 may be disposed at substantially the same level.

Source and drain regions 77 may be disposed in the active region 53 at both sides of the gate 84. The source and drain regions 77 may be high-concentration impurity regions. The active region 53, the gate 84 and the source and drain regions 77 may constitute a transistor.

The gate trench 66 may cross the active region 53 and the isolation layer 59. In this case, the gate 84 may extend to the isolation layer 59.

As shown in FIG. 14B, the top surface of the portion of the isolation layer 59 that is under the gate 84 may be disposed at a level lower than the top surface of the active region 53 under the gate 84. Even in this case, a “liner remaining area” 57S may be provided on both sidewalls of the active region 53 under the gate 84. That is, the liner 57 on both sidewalls of the active region 53 under the gate 84 may have a top surface that is at the same height or level above the bottom surface of the semiconductor substrate 51 as is the top surface of the portion of the isolation layer 59 that is under the gate 84.

A method of fabricating a semiconductor substrate in accordance with a second embodiment of the present invention may include forming the gate trench 66 (see FIG. 9A). Forming the gate trench 66 may include forming a hard mask pattern (not shown) on the semiconductor substrate 51, and etching the active region 53, the liner 57 and the isolation layer 59 using the hard mask pattern as an etching mask. The hard mask pattern may be formed of the same material layer as the liner 57. That is, the hard mask pattern may be formed of a nitride layer such as a silicon nitride layer.

The etching process for forming the gate trench 66 may comprise an anisotropic etching process that has different etch rates with respect to the active region 53, the liner 57 and the isolation layer 59. In this case, a top surface of the isolation layer 59 may be exposed on a bottom surface of the gate trench 66 at a level lower than the active region 53. In this process, top surfaces of the liner 57 and the isolation layer 59 may be formed to have the same level.

Next, the gate 84 may be formed in the gate trench 66. After forming the gate 84, the hard mask pattern is removed using, for example, an isotropic etching process. For instance, when the hard mask pattern is a silicon nitride layer, the hard mask pattern may be removed using dry etching or wet etching conditions having a high etch rate with respect to the silicon nitride layer.

The gate 84 may prevent introduction of an etching gas or an etching solution into the “liner remaining area” 57S. Therefore, although the liner 57 may comprise the same material as the hard mask pattern, it is possible to maintain the liner 57 on both sidewalls of the active region 53 under the gate 84.

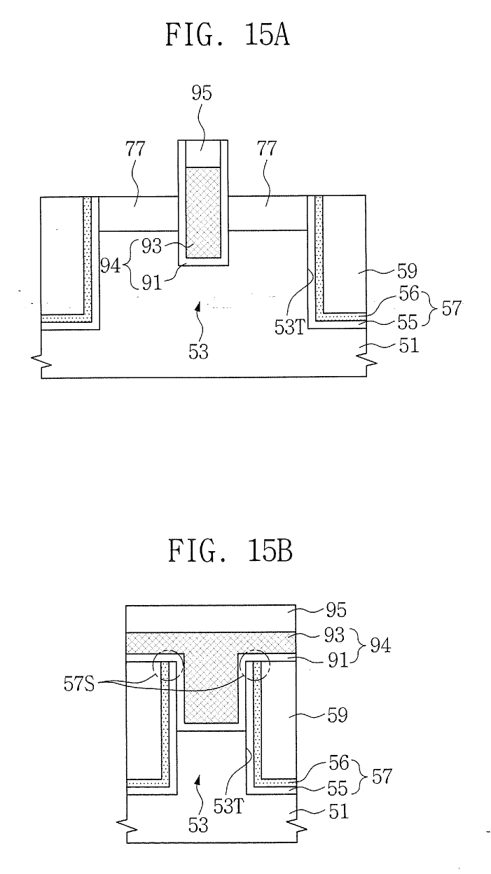

FIG. 15A is a cross-sectional diagram taken along line V-V′ of FIG. 6, illustrating methods of fabricating semiconductor devices having buried gates in accordance with third embodiments of the present invention. FIG. 15B is a cross-sectional diagram taken along line VII-VII′ of FIG. 6, illustrating methods of fabricating semiconductor devices having buried gates in accordance with the third embodiments of the present invention. Semiconductor devices and methods of fabricating the same in accordance with the third embodiments of the present invention will now be described with reference to FIGS. 6, 15A and 15B.

Referring to FIGS. 6, 15A and 15B, semiconductor devices in accordance with the third embodiments of the present invention may include an isolation layer 59 provided in the semiconductor substrate 51. The isolation layer 59 may fill an isolation trench 53T that defines an active region in the semiconductor substrate 51. The isolation layer 59 may comprise, for example, a silicon oxide layer. A liner 57 may be provided between the isolation layer 59 and the active region 53 so as to cover inner walls of the isolation trench 53T.

The liner 57 may include an inner liner 55 that covers sidewalls of the active region 53, and an outer liner 56 that covers the inner liner 55. The inner liner 55 may comprise, for example, a silicon oxide layer such as a thermal oxide layer. The outer liner 56 may comprise, for example, a nitride layer such as a silicon nitride layer. The liner 57 may be formed to a uniform thickness on the semiconductor substrate 51. In some embodiments, the inner liner 55 may be omitted.

A gate 94 crossing the active region 53 may be provided. The gate 94 may fill a gate trench 66 (see FIG. 9A) and project on the active region 53. The gate 94 may include a gate dielectric layer 91 covering inner walls of the gate trench 66, and a gate electrode 93 disposed on the gate dielectric layer 91. The gate electrode 93 may be disposed at a level higher than a top surface of the active region 53 adjacent to the gate 94.

The gate dielectric layer 91 may comprise, for example, a silicon oxide layer or a high-k dielectric layer. The gate electrode 93 may comprise, for example, a polysilicon layer, a metal silicide layer, a metal layer, or a combination thereof. The gate electrode 93 may be a titanium nitride (TiN) layer.

A gate capping pattern 95 may be provided on the gate electrode 93. The gate capping pattern 95 may comprise an insulating layer such as a silicon oxide layer. The gate capping pattern 95 may cover the gate 94.

Source and drain regions 77 may be disposed in the active region 53 at both sides of the gate 94. The source and drain regions 77 may be high-concentration impurity regions. The active region 53, the gate 94 and the source and drain regions 77 may constitute a transistor.

The gate trench 66 may cross the active region 53. As such, the gate 94 may extend onto the isolation layer 59. A top surface of the portion of the isolation layer 59 that is under the gate 94 may be disposed at a level higher than the top surface of the active region 53 under the gate 94. Even in this case, a “liner remaining area” 57S may be provided on both sidewalls of the active region 53 under the gate 94. That is, the liner 57 on both sidewalls of the active region 53 under the gate 94 may have top surfaces that are disposed at the same level as are the top surfaces of the portions of the isolation layer 59 that are under the gate 94.

In addition, when the top surface of the portion of the isolation layer 59 that is under the gate 94 is disposed at a level higher than the top surface of the active region 53 under the gate 94, the top surface of the liner 57 on both sidewalls of the active region 53 under the gate 94 may be at a level higher than the top surface of the active region 53 under the gate 94.

A method of fabricating a semiconductor device in accordance with the third embodiments of the present invention may include forming the gate trench 66 (see FIG. 9A). The gate trench 66 may be formed by forming a hard mask pattern (not shown) on the semiconductor substrate 51, and etching the active region 53, the liner 57 and the isolation layer 59 using the hard mask pattern as an etching mask. The hard mask pattern may be formed of the same material layer as the liner 57. That is, the hard mask pattern may be formed of a nitride layer such as a silicon nitride layer.

The etching process for forming the gate trench 66 may comprise an anisotropic etching process that has a higher etch rate with respect to the active region 53 than the liner 57 and the isolation layer 59. In this case, the gate trench 66 may be formed in the active region 53. The liner 57 may be maintained on sidewalls of the gate trench 66.

In addition, a top surface of the isolation layer 59 may be exposed on a bottom surface of the gate trench 66 at a level higher than the active region 53. In this process, top surfaces of the liner 57 and the isolation layer 59 may be formed to have the same level as the top surface of the exposed isolation layer 59.

The gate 94 may be formed to fill the gate trench 66 and extend to the isolation layer 59. After forming the gate 94, the hard mask pattern may be removed using, for example, an isotropic etching process. For example, when the hard mask pattern is formed of a silicon nitride layer, the hard mask pattern may be removed using dry etching or wet etching conditions having a high etch rate with respect to the silicon nitride layer.

In this case, the gate 94 may function to prevent introduction of an etching gas or an etching solution into the liner remaining area 57S. Therefore, although the liner 57 may comprise the same material as the hard mask pattern, it is possible to maintain the liner 57 on both sidewalls of the active region 53 under the gate 94.

As can be seen from the foregoing, according to embodiments of the present invention, methods of fabricating semiconductor devices are provided in which a liner and an isolation layer are formed in a semiconductor substrate, and then a hard mask pattern, a gate trench and a gate are formed. The hard mask pattern is removed after the gate is formed, and thus the gate functions to prevent the liner on both sidewalls of the active region under the gate from being in contact with an etching gas or an etching solution. Therefore, although the liner may comprise the same material layer as the hard mask pattern, it is possible to maintain the liner on both sidewalls of the active region under the gate.

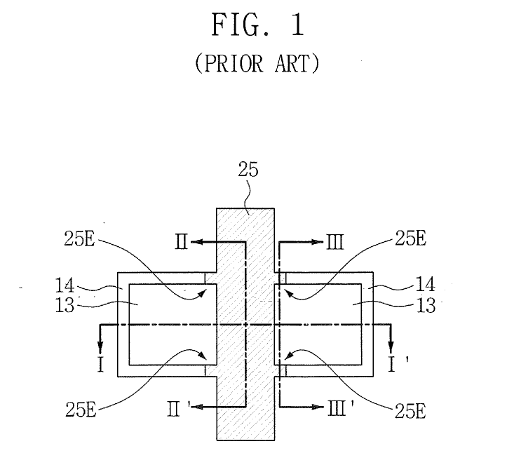

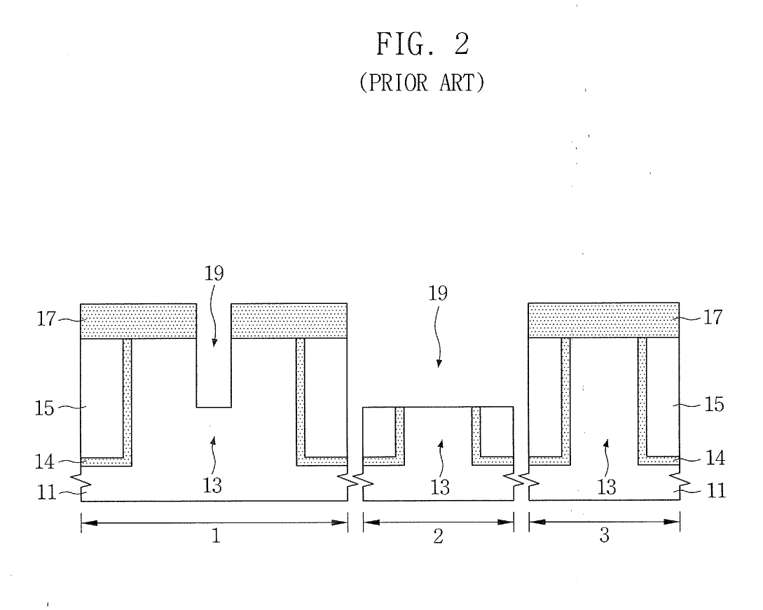

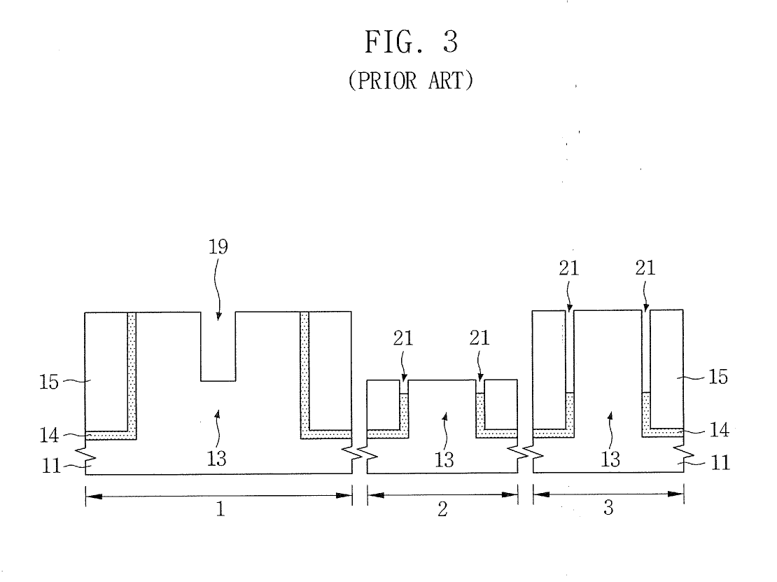

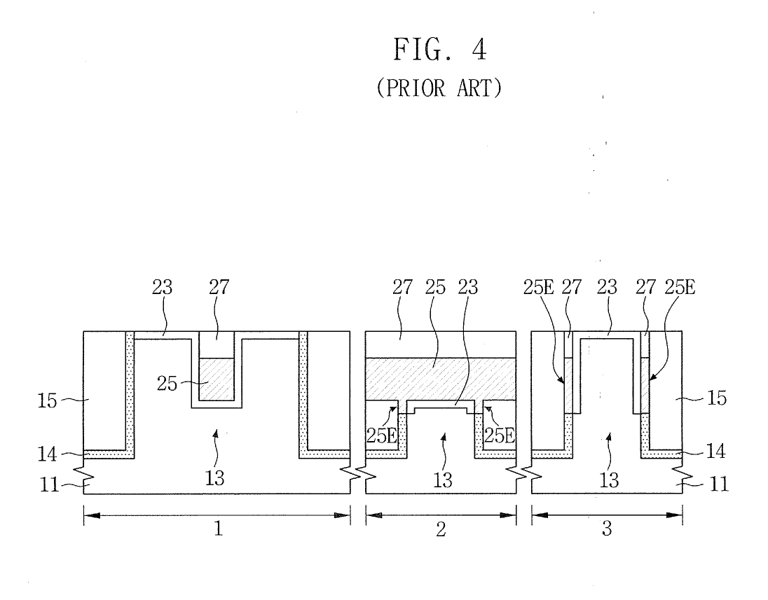

In contrast, in the conventional semiconductor device depicted in FIGS. 1-4, a portion of the liner may be removed during the removal of the hard mask layer and, as such, gate extension parts 25E may be formed. These gate extension parts 25E may form a parasitic transistor in the active region 13. The parasitic transistor may make it difficult to control electrical characteristics of a semiconductor device. For example, the parasitic transistor may deteriorate the refresh characteristics of a DRAM device. By maintaining the liner during the removal of the hard mask pattern, the methods according to embodiments of the present invention may provide semiconductor devices having good electrical characteristics.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A method of fabricating a semiconductor device, the method comprising:
forming an isolation trench in a semiconductor substrate to define an active region having sidewalls;
forming a liner on the sidewalls of the active region;
forming an isolation layer in the isolation trench;
forming a hard mask pattern on the semiconductor substrate having the liner and the isolation layer;
forming a gate trench that crosses over the active region using the hard mask pattern as an etching mask;
forming a gate in the gate trench, wherein the gate covers an exposed top surface of the liner; and
removing the hard mask pattern after forming the gate.

2. The method according to claim 1, wherein forming the gate trench comprises etching portions of the active region, the liner and the isolation layer.

3. The method according to claim 2, wherein the etching process is performed such that top surfaces of the etched portions of the active region, the liner and the isolation layer are etched to the same height above a bottom surface of the semiconductor substrate.

4. The method according to claim 2, wherein the etching process is performed such that top surfaces of the etched portions of the liner and the isolation layer have a lower level than a top surface of the etched portion of the active region.

5. The method according to claim 2, wherein the top surfaces of the etched portions of the liner and the isolation layer have the same level above a bottom surface of the semiconductor substrate.

6. The method according to claim 1, wherein the liner comprises a nitride layer.

7. The method according to claim 1, wherein forming the liner comprises forming an inner liner covering the sidewalls of the active region, and forming an outer liner covering the inner liner.

8. The method according to claim 1, wherein the hard mask pattern and the liner are formed of the same material.

9. The method according to claim 1, wherein the hard mask pattern comprises a nitride layer.

10. The method according to claim 1, wherein forming the gate comprises:
forming a gate dielectric layer in the semiconductor substrate having the gate trench; and
forming a gate electrode in the gate trench on the gate dielectric layer.

11. The method according to claim 10, wherein the gate electrode comprises a titanum nitride (TiN) layer.

12. The method according to claim 10, wherein a top surface of the gate electrode is lower than a top surface of the active region.

13. The method according to claim 1, further comprising:
forming a source region in the active region adjacent to a first side of the gate; and
forming a drain region in the active region adjacent to a second side of the gate.

14. The method according to claim 1, further comprising,
before forming the hard mask pattern,
forming a dummy dielectric layer on the active region; and
forming a dummy gate conductive layer on the dummy dielectric layer.

15. A semiconductor device comprising:
an isolation layer that defines an active region in a semiconductor substrate;
a liner between the active region and the isolation layer;
a gate disposed in a gate trench, the gate extending across the active region onto the liner and the isolation layer; and
a gate capping pattern on the gate,
wherein a top surface of the liner under the gate is disposed at the same level as a top surface of the isolation layer under the gate.

16. The semiconductor device according to claim 15, wherein the gate trench extends onto the isolation layer.

17. The semiconductor device according to claim 15, wherein a top surface of the isolation layer under the gate is disposed at a level lower than or equal to a top surface of the active region under the gate.

18. The semiconductor device according to claim 15, wherein the liner comprises a nitride layer.

19. The semiconductor device according to claim 15, wherein the liner comprises:
an inner liner covering sidewalls of the active region; and
an outer liner covering the inner liner.

20. The semiconductor device according to claim 15, wherein the gate comprises:
a gate electrode having a top surface that is lower than a top surface of the active region; and
a gate dielectric layer between the active region and the gate electrode.

21. The semiconductor device according to claim 15, wherein the gate capping pattern has a bottom surface that is lower than a top surface of the active region.

22. The semiconductor device according to claim 15, further comprising a source region in the active region on a first side of the gate and a drain region in the active region on a second side of the gate.
